(19) United States
(12) Patent Application Publication
(10) Pub. No.: US 2014/0093987 A1
(43) Pub. Date: Apr. 3, 2014

(54) Residue Detection with Spectrographic Sensor

(71) Applicant: Applied Materials, Inc., Santa Clara, CA (US)

(72) Inventors: Jeffrey Drue David, San Jose, CA (US); Boguslaw A. Swedek, Cupertino, CA (US); Wen-Chiang Tu, Mountain View, CA (US)

(21) Appl. No.: 13/791,622

(22) Filed: Mar. 8, 2013

Related U.S. Application Data
(60) Provisional application No. 61/708,888, filed on Oct. 2, 2012.

(51) Int. Cl. H01L 21/66; G01J 3/46; G01N 21/88

(52) U.S. Cl. CPC H01L 22/10; G01J 3/46; G01N 21/88
USPC 438/16; 356/402

(57) ABSTRACT

Detecting residue of a filler material over a patterned underlying layer includes causing relative motion between a probe of an optical metrology system and a substrate, obtaining a plurality of measured spectra with the optical metrology system through the probe from a plurality of different measurement spots within an area on the substrate, comparing each of the plurality of measured spectra to a reference spectrum to generate a plurality of similarity values, the reference spectrum being a spectrum reflected from the filler material, combining the similarity values to generate a scalar value, and determining the presence of residue based on the scalar value.

### CROSS-REFERENCE TO RELATED APPLICATIONS

This application claims priority to U.S. Provisional Application Ser. No. 61/708,888, filed Oct. 2, 2012, the entire disclosure of which is incorporated by reference.

### TECHNICAL FIELD

This disclosure relates to optical metrology, e.g., to detect residue on a substrate.

### BACKGROUND

An integrated circuit is typically formed on a substrate by the sequential deposition of conductive, semiconductive, or insulative layers on a silicon wafer. One fabrication step involves depositing a filler layer over a non-planar surface and planarizing the filler layer. For certain applications, the filler layer is planarized until the top surface of a patterned layer is exposed. A conductive filler layer, for example, can be deposited on a patterned insulative layer to fill the trenches or holes in the insulative layer. After planarization, the portions of the metallic layer remaining between the raised pattern of the insulative layer form vias, plugs, and lines that provide conductive paths between thin film circuits on the substrate. For other applications, such as oxide polishing, the filler layer is planarized until a predetermined thickness is left over the non planar surface. In addition, planarization of the substrate surface is usually required for photolithography.

Chemical mechanical polishing (CMP) is one accepted method of planarization. This planarization method typically requires that the substrate be mounted on a carrier or polishing head. The exposed surface of the substrate is typically placed against a rotating polishing pad. The carrier head provides a controllable load on the substrate to push it against the polishing pad. An abrasive polishing slurry is typically supplied to the surface of the polishing pad.

Variations in the slurry distribution, the polishing pad condition, the relative speed between the polishing pad and the substrate, and the load on the substrate can cause variations in the material removal rate. These variations, as well as variations in the initial thickness of the substrate layer, cause variations in the time needed to reach the polishing endpoint. Therefore, determining the polishing endpoint merely as a function of polishing time can lead to overpolishing or underpolishing of the substrate. Various in-situ monitoring techniques, such as optical or eddy current monitoring, can be used to detect a polishing endpoint.

One problem in CMP is conductive residue. For example, in the production of conductive vias, plugs and lines, the conductive filler layer should be polished until it is completely removed from the top surface of the underlying patterned layer. Otherwise, any conductive residue that remains can cause shorts or other defects. One technique to prevent residue is to overpolish the substrate, e.g., to continue polish past a detected polishing endpoint.

### SUMMARY

In some systems, the substrate is monitored in-situ during polishing, e.g., by optically or eddy current techniques. However, existing monitoring techniques may not reliably detect whether residue has been satisfactorily removed. A technique to detect residue is to measure spectra from the substrate and compare the measured spectra to a reference spectrum from a layer of the residue material.

In one aspect, a method of detecting residue of a filler material over a patterned underlying layer includes causing relative motion between a probe of an optical metrology system and a substrate, obtaining a plurality of measured spectra with the optical metrology system through the probe from a plurality of different measurement spots within an area on the substrate, comparing each of the plurality of measured spectra to a reference spectrum to generate a plurality of similarity values, the reference spectrum being a spectrum reflected from the filler material, combining the similarity values to generate a scalar value, and determining the presence of residue based on the scalar value.

Implementations may include one or more of the following features. The substrate may include a plurality of dies, and the area may be substantially equal to an area of one of the dies. The plurality of different measurement spots may include at least 100 measurement spots. The plurality of different measurement may be distributed with substantially uniform density across the area. Causing relative motion may include holding the substrate in a fixed position in a carrier head and moving the probe. Moving the probe may include moving the probe in a path that includes a plurality of equally spaced parallel line segments. Moving the probe may include moving the probe with an XY actuator. Causing relative motion may include moving a carrier head holding the substrate while the probe remains in a fixed position. The substrate may be polished at a first polishing station and at a second polishing station, and the probe may be positioned between the first polishing station and the second polishing station. Polishing the substrate at the first polishing station may include a filler layer clearing recipe, and polishing the substrate at the second polishing station may include an underlying layer polishing recipe. The filler material may be a metal, e.g., copper, and the underlying layer may be barrier layer, e.g., tantalum nitride. Comparing each of the plurality of measured spectra to the reference spectrum may include calculating a sum of squared differences between each of the plurality of measured spectra and the reference spectrum. Comparing each of the plurality of measured spectra to the reference spectrum may include calculating a cross-correlation between each of the plurality of measured spectra and the reference spectrum. Combining the similarity values may include averaging the similarity values. Combining the similarity values may include comparing each similarity value of the plurality of similarity values to a threshold, and determining whether to set each similarity value to a preset value based on the comparison. Similarity values that indicate less similarity to the reference spectrum than the threshold value may be set to the preset value. Determining the presence of residue may include comparing the scalar value to a threshold. Whether to at least one of return the substrate to a polishing station for rework or return the substrate to a cassette may be determined based on the presence of residue.

Implementations can include one or more of the following potential advantages. Residue, e.g., copper, can be reliably detected. An overall amount of filler material on a die can be measured and compared to the expected amount of filler material. If the die is not sufficiently cleared, the substrate can be returned to a polishing station for rework. The residue information can be used to adjust a subsequent polishing operation to ensure complete removal of the residue. A map of residue over a die can be generated.

The details of one or more implementations are set forth in the accompanying drawings and the description below. Other aspects, features and advantages will be apparent from the description and drawings, and from the claims.

### DESCRIPTION OF DRAWINGS

FIG. 1 illustrates a plan view of an example of a polishing apparatus.

FIG. 2 illustrates a cross-sectional view of an example of a polishing apparatus.

FIG. 3 illustrates a view of an example of an in-line optical measurement system.

FIG. 4 illustrates an example spectrum.

FIG. 5 illustrates a top view of an example of a substrate having dies.

FIG. 6 illustrates a top view of a die showing portions composed of filler material.

FIG. 7 illustrates a top view of an example of a path of a light beam from the optical metrology system over a die.

FIG. 8 illustrates a cross-sectional view of another example of a polishing apparatus.

Like reference symbols in the various drawings indicate like elements.

### DETAILED DESCRIPTION

In some semiconductor chip fabrication processes, an overlying filler layer, for example, a conductive material, e.g., a metal, such copper or tungsten, or polysilicon, or a dielectric, e.g. silicon oxide, is polished until an underlying layer of a different material, e.g., a dielectric, such as silicon oxide, silicon nitride or a high-K dielectric, is exposed. For some applications the underlying layer is patterned, so when the top surface of the overlying layer is exposed, portions of the filler layer remain between the raised pattern of the underlying layer. Because some area of the substrate retains the filler layer, in-situ optical detection of residue is difficult; there can be uncertainty in whether a particular measurement corresponds to a spot that is expected to retain the filler layer.

A technique to detect residue is to measure spectra from the substrate and compare the measured spectra to a reference spectrum from a filler layer. Multiple measurements can be made over a region of the substrate, e.g., a region equivalent to an area of a die. The average similarity to the reference spectrum across the area can be calculated, and compared to an expected value to determine the presence of residue. Alternatively, the density of regions with the filler layer can be compared to an expected density to determine the presence of residue.

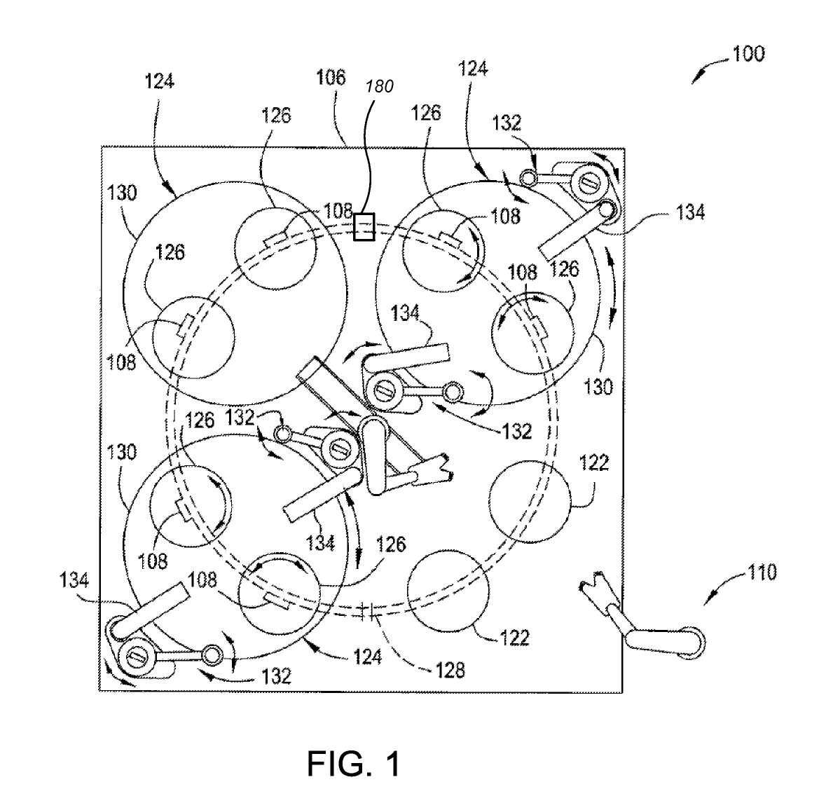

FIG. 1 is a plan view of a chemical mechanical polishing apparatus 100 for processing one or more substrates. The polishing apparatus 100 includes a polishing platform 106 that at least partially supports and houses one or more polishing stations 124. The polishing apparatus 100 also includes a multiplicity of carrier heads 126, each of which is configured to carry a substrate. Each polishing station 124 is adapted to polish a substrate that is retained in a carrier head 126.

The polishing apparatus 100 can also include one or more load cups 122 adapted to facilitate transfer of a substrate between the carrier heads 126 and a factory interface (not shown) or other device (not shown) by a transfer robot 110. The load cups 122 generally facilitate transfer between the robot 110 and each of the carrier heads 126.

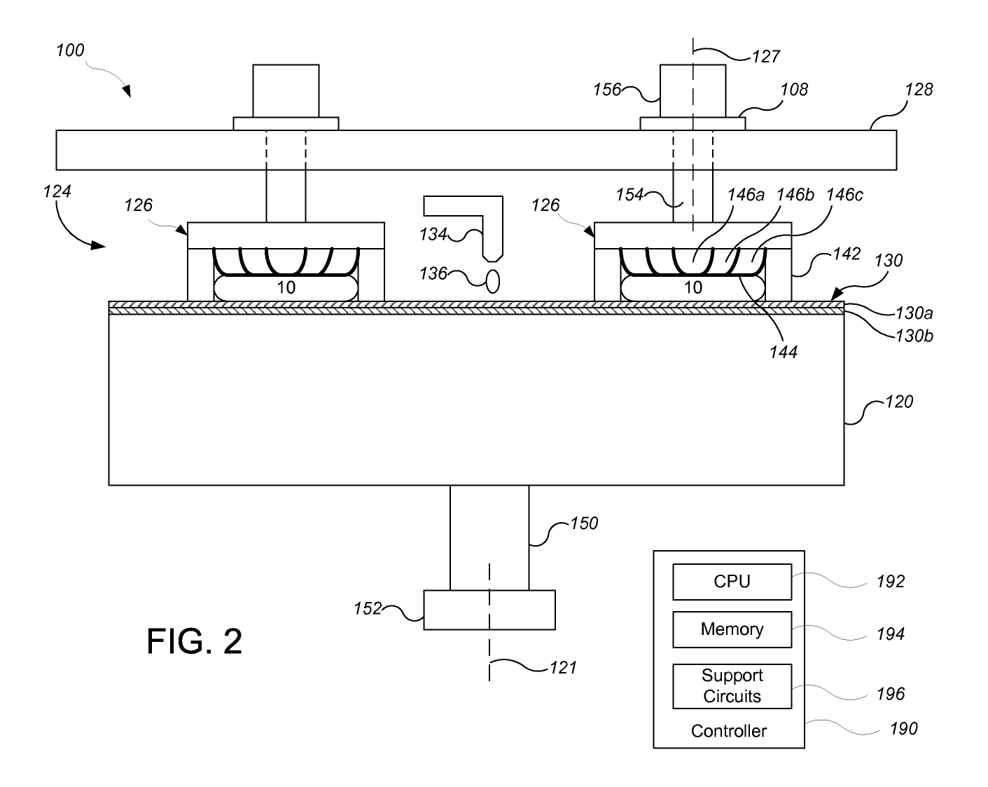

Each polishing station 124 includes a polishing pad 130 supported on a platen 120 (see FIG. 2). The polishing pad 110 can be a two-layer polishing pad with an outer polishing layer 130a and a softer backing layer 130b (see FIG. 2).

In some implementations, at least one of the polishing stations 124 is sized such that a plurality of carrier heads 126 can be positioned simultaneously over the polishing pad 130 so that polishing of a plurality of substrates can occur at the same time in the polishing station 124. Thus, a plurality of substrates, e.g., one per carrier head, can be polished simultaneously with the same polishing pad. Alternatively, in some implementations there is just one carrier head 126 per polishing pad 130. In addition, although six carrier heads 126 are shown, more or fewer carrier heads can be depending on the needs of the polishing process and so that the surface area of polishing pad 130 may be used efficiently.

In some implementations, the carrier heads 126 are coupled to a carriage 108 that is mounted to an overhead track 128. The overhead track 128 allows each carriage 108 to be selectively positioned over the polishing stations 124 and the load cups 122. In the implementation depicted in FIG. 1, the overhead track 128 has a circular configuration (shown in phantom) which allows the carriages 108 retaining the carrier heads 126 to be selectively orbited over and/or clear of the load cups 122 and the polishing stations 124. The overhead track 128 may have other configurations including elliptical, oval, linear or other suitable orientation. Alternatively, in some implementations the carrier heads 126 are suspended from a carousel, and rotation of the carousel moves all of the carrier heads simultaneously along a circular path.

Each polishing station 124 of the polishing apparatus 100 can include a port, e.g., at the end of an arm 134, to dispense polishing liquid 136 (see FIG. 2), such as abrasive slurry, onto the polishing pad 130. Each polishing station 124 of the polishing apparatus 100 can also include pad conditioning apparatus 132 to abrade the polishing pad 130 to maintain the polishing pad 130 in a consistent abrasive state.

As shown in FIG. 2, the platen 120 at each polishing station 124 is operable to rotate about an axis 121. For example, a motor 150 can turn a drive shaft 152 to rotate the platen 120.

Each carrier head 126 is operable to hold a substrate 10 against the polishing pad 130. Each carrier head 126 can have independent control of the polishing parameters, for example pressure, associated with each respective substrate. In particular, each carrier head 126 can include a retaining ring 142 to retain the substrate 10 below a flexible membrane 144. Each carrier head 126 also includes a plurality of independently controllable pressurizable chambers defined by the membrane, e.g., three chambers 146a-146c, which can apply independently controllable pressurizes to associated zones on the flexible membrane 144 and thus on the substrate 10. Although only three chambers are illustrated in FIG. 2 for ease of illustration, there could be one or two chambers, or four or more chambers, e.g., five chambers.

Each carrier head 126 is suspended from the track 128, and is connected by a drive shaft 154 to a carrier head rotation motor 156 so that the carrier head can rotate about an axis 127. Optionally each carrier head 140 can oscillate laterally, e.g., by driving the carriage 108 on the track 128, or by rotational oscillation of the carousel itself. In operation, the platen is rotated about its central axis 121, and each carrier head is rotated about its central axis 127 and translated laterally across the top surface of the polishing pad. The lateral sweep is in a direction parallel to the polishing surface 212. The lateral sweep can be a linear or arcuate motion.

A controller 190, such as a programmable computer, is connected to each motor 152, 156 to independently control the rotation rate of the platen 120 and the carrier heads 126. For example, each motor can include an encoder that measures the angular position or rotation rate of the associated drive shaft. Similarly, the controller 190 is connected to an actuator in each carriage 108 to independently control the lateral motion of each carrier head 126. For example, each actuator can include a linear encoder that measures the position of the carriage 108 along the track 128.

The controller 190 can include a central processing unit (CPU) 192, a memory 194, and support circuits 196, e.g., input/output circuitry, power supplies, clock circuits, cache, and the like. The memory is connected to the CPU 192. The memory is a non-transitory computable readable medium, and can be one or more readily available memory such as random access memory (RAM), read only memory (ROM), floppy disk, hard disk, or other form of digital storage. In addition, although illustrated as a single computer, the controller 190 could be a distributed system, e.g., including multiple independently operating processors and memories.

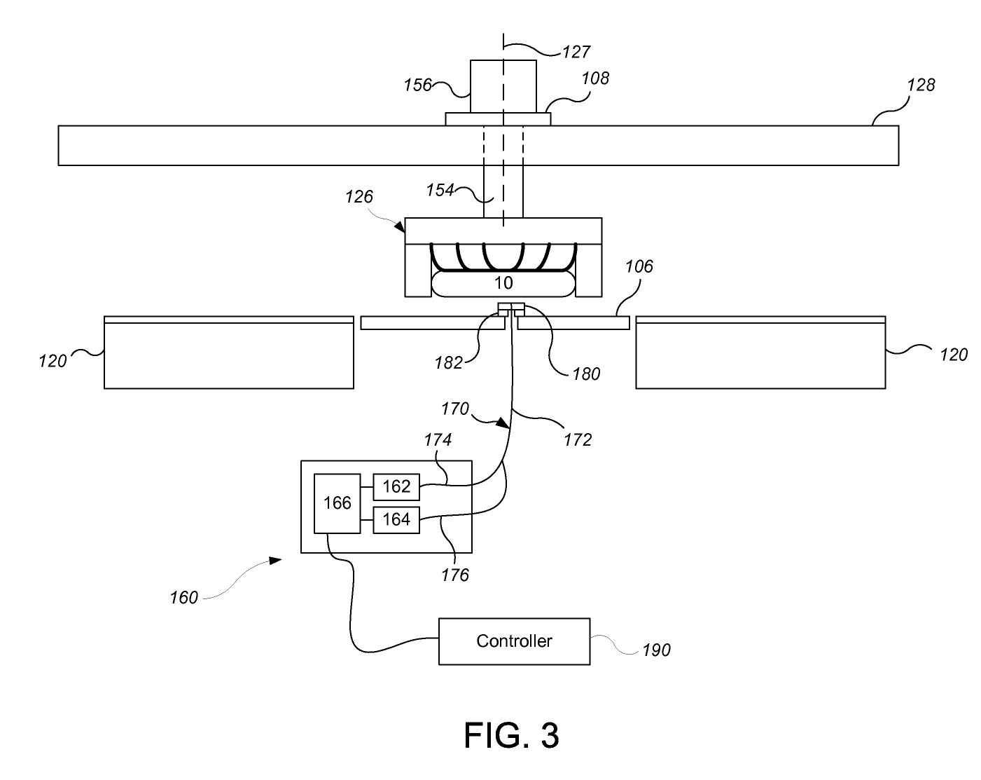

Referring to FIGS. 1 and 3, the polishing apparatus 100 also includes an in-line (also referred to as in-sequence) optical metrology system 160, e.g., a spectrographic metrology system, which can be used to determine the presence of residue on the substrate 10. An in-line metrology system is positioned within the polishing apparatus 100, but does not performs measurements during the polishing operation; rather measurements are collected between polishing operations, e.g., while the substrate is being moved from one polishing station to another or to the load cup.

The in-line optical metrology system 160 includes a probe 180 supported on the platform 106 at a position between two of the polishing stations 124, e.g., between two platens 120. In particular, the probe 180 is located at a position such that a carrier head 126 supported by the track 128 can position the substrate 10 over the probe 170. In implementations in which the polishing apparatus 100 include three polishing stations and carries the substrates sequentially from the first polishing station to the second polishing station to the third polishing station, the probe 180 can be positioned between the second and third polishing stations.

More particularly, the probe 180 should be positioned after a station at which the filler layer is expected to be cleared. For example, where the controller 190 is configured with a recipe to perform bulk polishing (but not clearance) of the filler layer at a first polishing station, clearance of the filler layer at a second polishing station, and removal or clearing of an underlying layer at a third polishing station, the probe 180 can be positioned between the second and third polishing stations. In particular, for a copper polishing process that has bulk copper polishing at the first polishing station, clearance of copper at the second polishing station, and clearing of a barrier layer and a cap layer at the third polishing station, the probe 180 can be positioned between the second and third polishing stations.

The optical metrology system 160 can include a light source 162, a light detector 164, and circuitry 166 for sending and receiving signals between the controller 190 and the light source 162 and light detector 164.

One or more optical fibers can be used to transmit the light from the light source 162 to the optical access in the polishing pad, and to transmit light reflected from the substrate 10 to the detector 164. For example, a bifurcated optical fiber 170 can be used to transmit the light from the light source 162 to the substrate 10 and back to the detector 164. The bifurcated optical fiber can include a trunk 172 having an end in the probe 180 to measure the substrate 10, and two branches 174 and 176 connected to the light source 162 and detector 164, respectively.

In some implementations, the probe 180 holds an end of the trunk 172 of the bifurcated fiber. In operation, the carrier head 126 positions a substrate 10 over the probe 180. Light from the light source 162 is emitted from the end of the trunk 172, reflected by the substrate 10 back into the trunk 172, and the reflected light is received by the detector 164. In some implementations, one or more other optical elements, e.g., a focusing lens, are positioned over the end of the trunk 172, but these may not be necessary.

The probe 180 can include a mechanism to adjust the vertical height of the end the trunk 172, e.g., the vertical distance between the end of the trunk 172 and the top surface of the platform 106. In some implementations, the probe 180 is supported on an actuator system 182 that is configured to move the probe 180 laterally in a plane parallel to the plane of the track 128. The actuator system 182 can be an XY actuator system that includes two independent linear actuators to move probe 180 independently along two orthogonal axes.

The output of the circuitry 166 can be a digital electronic signal that passes to the controller 190 for the optical metrology system. Similarly, the light source 162 can be turned on or off in response to control commands in digital electronic signals that pass from the controller 190 to the optical metrology system 160. Alternatively, the circuitry 166 could communicate with the controller 190 by a wireless signal.

The light source 162 can be operable to emit white light. In one implementation, the white light emitted includes light having wavelengths of 200-800 nanometers. A suitable light source is a xenon lamp or a xenon mercury lamp.

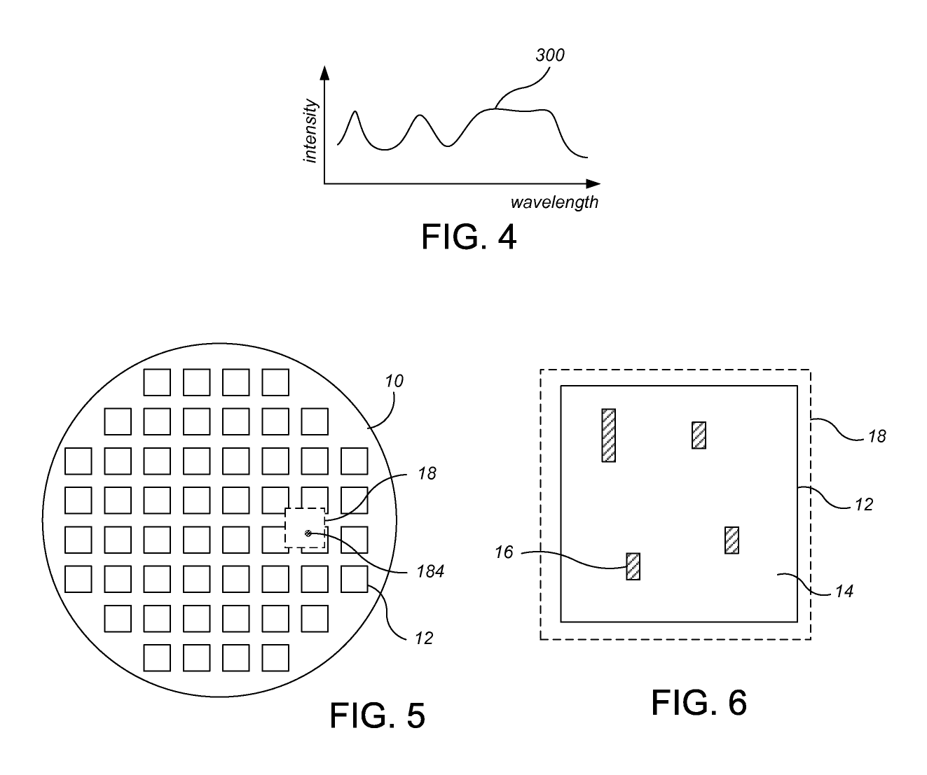

The light detector 164 can be a spectrometer. A spectrometer is an optical instrument for measuring intensity of light over a portion of the electromagnetic spectrum. A suitable spectrometer is a grating spectrometer. Typical output for a spectrometer is the intensity of the light as a function of wavelength (or frequency). FIG. 4 illustrates an example of a measured spectrum 300.

As noted above, the light source 162 and light detector 164 can be connected to a computing device, e.g., the controller 190, operable to control their operation and receive their signals. The computing device can include a microprocessor situated near the polishing apparatus, e.g., a programmable computer. With respect to control, the computing device can, for example, synchronize activation of the light source with the motion of the carrier head 126.

Referring to FIG. 5, a typical substrate 10 includes multiple dies 12. Referring to FIG. 6, as noted above, because the underlying layer is patterned, a die 12 will include regions 14 where, in an ideal polishing situation, the filler layer would be completely removed, and regions 16 where filler material remains between the raised portions of the patterned underlying layer.

In some implementations, the controller 190 causes the substrate 10 and the probe 180 to undergo relative motion so that the optical metrology system 160 can make multiple measurements within an area 18 (see FIG. 5) on the substrate 10. In particular, the optical metrology system 160 can take multiple measurements at spots 184 (only one spot is shown on FIG. 5 for clarity) that are spread out with a substantially uniform density over the area 18. The area 18 can be equivalent to the area of a die 12. In some implementations, the die 12 (and the area 18) can be considered to include half of any adjacent scribe line. In some implementations, at least one-hundred measurements are made within the area 18. For example, if a die is 1 cm on a side, then the measurements can be made at 1 mm intervals across the area. The edges of the area 18 need not be aligned with the edges of a particular die 12 on the substrate. Instead, what is important is that a sufficient number of measurements be taken at a sufficient number of different locations across the area 18 such that a percentage area occupied by the filler material within the area 18 can be reliably calculated.

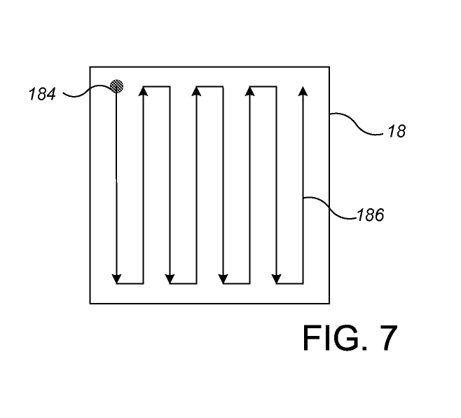

In some implementations, the XY actuator system 182 causes the measurement spot 184 of the probe 180 to traverse a path 186 across the area 18 on the substrate 10 while the carrier head 126 holds the substrate 10 in a fixed position (relative to the platform 106). For example, referring to FIG. 7, the XY actuator system 182 can cause the measurement spot 184 to traverse a path 186 which traverses the area 18 on a plurality of evenly spaced parallel line segments. This permits the optical metrology system 160 to take measurements that are evenly spaced over the area 18.

In some implementations, there is no actuator system 182, and the probe 180 remains stationary (relative to the platform 106) while the carrier head 126 moves to cause the measurement spot 184 to traverse the area 18. For example, the carrier head could undergo a combination of rotation (from motor 156) translation (from carriage 108 moving along track 128) to cause the measurement spot 184 to traverse the area 18. For example, the carrier head 126 can rotate while carriage 108 causes the center of the substrate to move outwardly from the probe 180, which causes the measurement spot 184 to traverse a spiral path on the substrate 10. By making measurements while the spot 184 is over the area 18, measurements can be made at a substantially uniform density over the area 18.

In some implementations, the relative motion is caused by a combination of motion of the carrier head 126 and motion of the probe 180, e.g., rotation of the carrier head 126 and linear translation of the probe 180.

The controller 190 receives a signal from the optical metrology system 160 that carries information describing a spectrum of the light received by the light detector for each flash of the light source or time frame of the detector.

Without being limited to any particular theory, the spectrum of light reflected from the substrate 10 will vary across the area 18 due to the presence of the filler material, either due to the areas 16 where the filler material is expected, or due to residue on areas 14 where the filler layer is expected to be completely removed.

In order to evaluate the percentage of the area that is covered by the filler material, each measured spectrum 300 is compared to a reference spectrum. The reference spectrum can be the spectrum from a thick layer of the filler material, e.g., a spectrum from a metal, e.g., a copper or tungsten reference spectrum. The comparison generates a similarity value for each measured spectrum 300. A single scalar value representing the amount of filler material within the area 18 can be calculated from the similarity values, e.g., by averaging the similarity values. The scalar value can then be compared to a threshold to determine the presence and/or amount of residue in the area.

In some implementations, the similarity value is calculated from a sum of squared differences between the measured spectrum and the reference spectrum. In some implementations, the similarity value is calculated from a cross-correlation between the measured spectrum and the reference spectrum.

For example, in some implementation a sum of squared differences (SSD) between each measured spectrum and the reference spectrum is calculated to generate an SSD value for each measurement spot. The SSD values can then be normalized by dividing all SSD values by the highest SSD value obtained in the scan to generate normalized SSD values (so that the highest SSD value is equal to 1). The normalized SSD values are then subtracted from 1 to generate the similarity value. The spectrum that had the highest SSD value, and thus the smallest copper contribution, is now equal to 0.

Then the average of all similarity values generated in the prior step is calculated to generate the scalar value. This scalar value will be higher if residue is present.

As another example, in some implementation a sum of squared differences (SSD) between each measured spectrum and the reference spectrum is calculated to generate an SSD value for each measurement spot. The SSD values can then be normalized by dividing all SSD values by the highest SSD value obtained in the scan to generate normalized SSD values (so that the highest SSD value is equal to 1). The normalized SSD values are then subtracted from 1 to generate inverted normalized SSD values. For a given spectrum, if the inverted normalized SSD value generated in the previous step is less than a user-defined threshold, then it is set to 0. The user-defined threshold can be 0.5 to 0.8, e.g., 0.7. Then the average of all values generated in the prior step is calculated to generate the scalar value. Again, this similarity value will be higher if residue is present.

If the calculated scalar value is greater than a threshold value, then the controller 190 can designate the substrate as having residue. On the other hand, if the scalar value is equal or less than the threshold value, then the controller 190 can designate the substrate as not having residue.

If the controller 190 does not designate the substrate as having residue, then the controller can cause the substrate to be processed at the next polishing station normally. On the other hand, controller 190 designates the substrate as having residue, then the controller can take a variety of actions. In some implementations, the substrate can be returned immediately to the previous polishing station for rework. In some implementations, the substrate is returned to the cassette (without being processed at a subsequent polishing station) and designated for rework once other substrates in the queue have completed polishing. In some implementations, the substrate is returned to the cassette (without being processed at a subsequent polishing station), and an entry for the substrate in a tracking database is generated to indicate that the substrate has residue. In some implementations, the scalar value can be used to adjust a subsequent polishing operation to ensure complete removal of the residue. In some implementations, the scalar value can be used to flag the operator that something has gone wrong in the polishing process, and that the operator's attention is required. The tool can enter into a number of error/alarm states, e.g. return all substrates to a cassette and await operator intervention.

In another implementation, the calculated similarity value for each measurement value is compared to a threshold value. Based on the comparison, each measurement spot is designated as either filler material or not filler material. For example, if an inverted normalized SSD value is generated for each measurement spot as discussed above, then the user-defined threshold can be 0.5 to 0.8, e.g., 0.7.

The percentage of measurement spots within the area 18 that are designated as filler material can be calculated. For example, the number of measurement spots designated as filler material can be divided by the total number of measurement spots.

This calculated percentage can be compared to a threshold percentage. The threshold percentage can be calculated either from knowledge of pattern of the die on the substrate, or empirically by measuring (using the measurement process described above) for a sample substrate that is known to not have residue. The sample substrate could be verified as not having residue by a dedicated metrology station.

If the calculated percentage is greater than the threshold percentage, then the substrate can be designated as having residue. On the other hand, if the percentage is equal or less than the threshold percentage, then the substrate can be designated as not having residue. The controller 190 can then take action as discussed above.

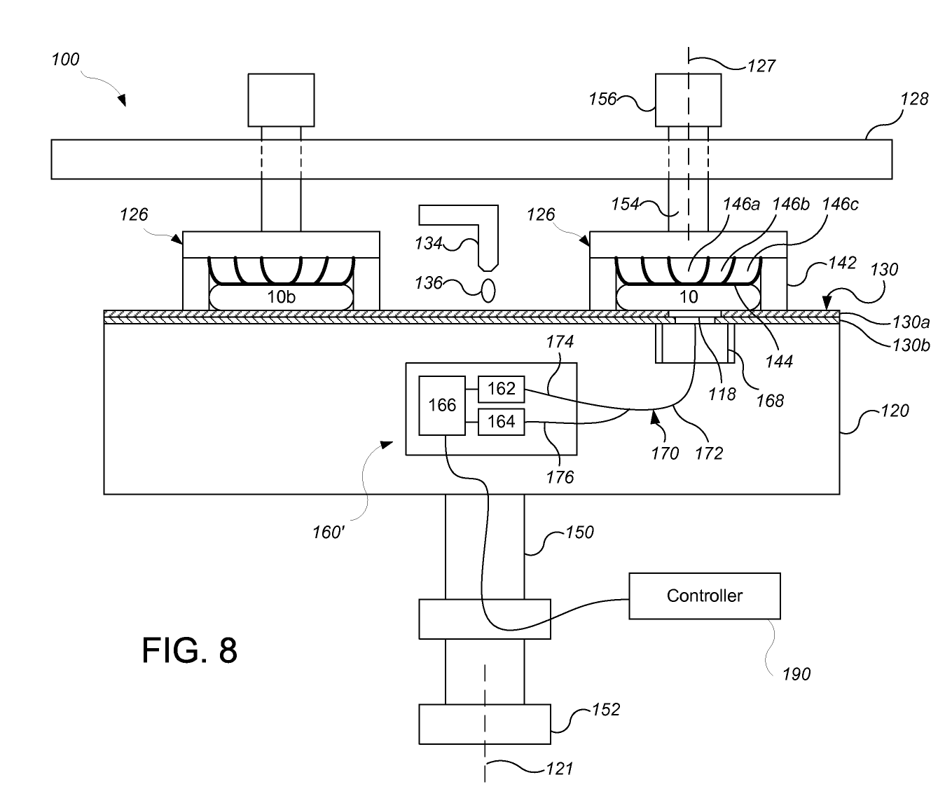

Referring to FIG. 8, it may be possible to apply the techniques described above to an in-situ monitoring system 160′. In this case, an optical access through the polishing pad is provided by including an aperture (i.e., a hole that runs through the pad) or a solid window 118. The solid window 118 can be secured to the polishing pad 110, e.g., as a plug that fills an aperture in the polishing pad, e.g., is molded to or adhesively secured to the polishing pad, although in some implementations the solid window can be supported on the platen 120 and project into an aperture in the polishing pad. For the in-situ, case, the residue value can be used to control endpoint. When the controller determines that the scalar value reaches a particular endpoint threshold, it can be determined that no residue is present, and the controller can halt the polishing process.

The above described polishing apparatus and methods can be applied in a variety of polishing systems. For example, rather than be suspended from a track, multiple carrier heads can be suspended from a carousel, and lateral motion of the carrier heads can be provided by a carriage that is suspend from and can move relative to the carousel. The platen may orbit rather than rotate. Although a plurality of polishing stations are illustrated in FIG. 1, there could be just a single polishing station. The polishing pad can be a circular (or some other shape) pad secured to the platen. Some aspects of the endpoint detection system may be applicable to linear polishing systems (e.g., where the polishing pad is a continuous or a reel-to-reel belt that moves linearly). The polishing layer can be a standard (for example, polyurethane with or without fillers) polishing material, a soft material, or a fixed-abrasive material. Terms of relative positioning are used; it should be understood that the polishing surface and substrate can be held in a vertical orientation or some other orientations.

While the foregoing is directed to embodiments of the present invention, other and further embodiments of the invention may be devised without departing from the basic scope thereof, and the scope thereof is determined by the claims that follow.

What is claimed is:

1. A method of detecting residue of a filler material over a patterned underlying layer, comprising:
causing relative motion between a probe of an optical metrology system and a substrate;
obtaining a plurality of measured spectra with the optical metrology system through the probe from a plurality of different measurement spots within an area on the substrate;
comparing each of the plurality of measured spectra to a reference spectrum to generate a plurality of similarity values, the reference spectrum being a spectrum reflected from the filler material;
combining the similarity values to generate a scalar value; and
determining the presence of residue based on the scalar value.

2. The method of claim 1, wherein the substrate comprises a plurality of dies, and the area is substantially equal to an area of one of the dies.

3. The method of claim 1, wherein the plurality of different measurement spots comprises at least 100 measurement spots.

4. The method of claim 1, wherein the plurality of different measurement are distributed with substantially uniform density across the area.

5. The method of claim 1, wherein causing relative motion comprises holding the substrate in a fixed position in a carrier head and moving the probe.

6. The method of claim 5, wherein moving the probe comprises moving the probe in a path that includes a plurality of equally spaced parallel line segments.

7. The method of claim 5, wherein moving the probe comprises moving the probe with an XY actuator.

8. The method of claim 1, wherein causing relative motion comprises moving a carrier head holding the substrate while the probe remains in a fixed position.

9. The method of claim 1, comprising polishing the substrate at a first polishing station, and polishing the substrate at a second polishing station, and wherein the probe is positioned between the first polishing station and the second polishing station.

10. The method of claim 9, wherein the polishing the substrate at the first polishing station comprises a filler layer clearing recipe, and polishing the substrate at the second polishing station comprises an underlying layer polishing recipe.

11. The method of claim 1, wherein the filler material is a metal.

12. The method of claim 11, wherein the filler material is copper.

13. The method of claim 11, wherein the underlying layer is barrier layer.

14. The method of claim 1, wherein comparing each of the plurality of measured spectra to the reference spectrum comprises calculating a sum of squared differences between each of the plurality of measured spectra and the reference spectrum.

15. The method of claim 1, wherein comparing each of the plurality of measured spectra to the reference spectrum comprises calculating a cross-correlation between each of the plurality of measured spectra and the reference spectrum.

16. The method of claim 1, wherein combining the similarity values comprises averaging the similarity values.

17. The method of claim 1, wherein combining the similarity values comprises comparing each similarity value of the plurality of similarity values to a threshold, and determining whether to set each similarity value to a preset value based on the comparison.

18. The method of claim 17, comprising setting similarity values that indicate less similarity to the reference spectrum than the threshold value to the preset value.

19. The method of claim 1, wherein determining the presence of residue comprises comparing the scalar value to a threshold.

20. The method of claim 1, further comprising determining based on the presence of residue whether to at least one of return the substrate to a polishing station for rework or return the substrate to a cassette.
